(19) United States
(12) Patent Application Publication
(10) Pub. No.: US 2017/0069565 A1
(43) Pub. Date: Mar. 9, 2017

(54) INTEGRATED CIRCUIT PACKAGING SYSTEM WITH SINGLE-LAYER SUPPORT STRUCTURE

(71) Applicant: STATS ChipPAC Pte. Ltd., Singapore (SG)

(72) Inventors: BONG WOO CHOI, Seoul (KR); SUNGSOO KIM, Seoul (KR); HYUNGSANG PARK, Gyeonggi-do (KR); JIWON JANG, SEOUL (KR)

(21) Appl. No.: 15/257,770

(22) Filed: Sep. 6, 2016

Related U.S. Application Data
(60) Provisional application No. 62/214,453, filed on Sep. 4, 2015.

(51) Int. Cl. H01L 23/498; H01L 21/48; H01L 21/52; H01L 23/31; H01L 21/56

(52) U.S. Cl. CPC H01L 23/49827; H01L 23/3121; H01L 23/49894; H01L 23/49811; H01L 21/56; H01L 21/52; H01L 21/4803

(57) ABSTRACT

Approaches, techniques, and mechanisms are disclosed for a method of manufacturing an integrated circuit package with a single-layer substrate. In an embodiment, the inventive integrated circuit package not only reduces manufacture cost but also improves reliability and miniaturization. According to an embodiment, a single-layer substrate is manufactured using non-photoimageable dielectric (NPID) material that is different from other dielectric materials, such as PrePreg (PPG) materials, copper clad laminates (CCL), solder resists (SR), and so forth, that are used in conventional substrates. A single-layer substrate manufactured using the NPID material provides a low cost solution by, among other aspects, eliminating certain process steps, such as a laser drill process, that are often used to manufacture the other substrates. According to an embodiment, the NPID material utilized for the described techniques and systems may feature a low coefficient of thermal expansion (CTE), a high glass transition temperature (Tg), and/or a high modulus compared to the other dielectric materials. Such features improve reliability because of, among other aspects, improved trace protection and peel strength, thereby enhancing adhesion between traces (e.g., of copper (Cu), etc.) and dielectric materials. In an embodiment, such features also improve miniaturization because, for example, the NPID material may allow formation of traces with reduced geometry.

### PRIORITY CLAIM

This application claims benefit of Provisional Application No. 62/214,453, filed Sep. 4, 2015, the entire contents of which are hereby incorporated by reference as if fully set forth herein, under 35 U.S.C. §119(e).

### TECHNICAL FIELD

Embodiments relate generally to an integrated circuit packaging system, and, more specifically, to techniques for substrate formation.

### BACKGROUND

The approaches described in this section are approaches that could be pursued, but not necessarily approaches that have been previously conceived or pursued. Therefore, unless otherwise indicated, it should not be assumed that any of the approaches described in this section qualify as prior art merely by virtue of their inclusion in this section.

Increased miniaturization of components, greater packaging density of integrated circuits (ICs), higher performance, and lower cost are ongoing goals of the computer industry. Semiconductor package structures continue to advance toward miniaturization, to increase the density of the components that are packaged therein while decreasing the sizes of the products that are made therefrom. This is in response to continually increasing demands on information and communication products for ever-reduced sizes, thicknesses, and costs, along with ever-increasing performance.

These increasing requirements for miniaturization are particularly noteworthy, for example, in portable information and communication devices such as cellular phones, hands-free cellular phone headsets, personal data assistants (PDAs), camcorders, notebook computers, and so forth. All of these devices continue to be made smaller and thinner to improve their portability. Accordingly, large-scale IC (LSI) packages that are incorporated into these devices are required to be made smaller and thinner. The package configurations that house and protect LSI require them to be made smaller and thinner as well.

Consumer electronics requirements demand more integrated circuits in an integrated circuit package while paradoxically providing less physical space in the system for the increased integrated circuits content. Continuous cost reduction is another requirement. Some technologies primarily focus on integrating more functions into each integrated circuit. Other technologies focus on stacking these integrated circuits into a single package. While these approaches provide more functions within an integrated circuit, they do not fully address the requirements for integration and cost reduction.

### BRIEF DESCRIPTION OF THE DRAWINGS

The present invention is illustrated by way of example, and not by way of limitation, in the figures of the accompanying drawings and in which like reference numerals refer to similar elements and in which:

FIG. 1 is a cross-sectional view of an integrated circuit packaging system in which techniques described herein may be practiced, according to an embodiment;

FIG. 2 is a bottom view of an integrated circuit packaging system;

FIG. 3 is a cross-sectional view of a carrier used in an initial step of a process flow for manufacture of an integrated circuit packaging system with a support structure without a detach carrier;

FIG. 4 illustrates metal-one (M1) layers formed directly on top layers, in accordance with a patterning step;

FIG. 5 illustrates insulation layers formed directly on M1 layers, in accordance with a lamination step;

FIG. 6 illustrates base conductive layers formed directly on insulation layers, in accordance with a pressing step;

FIG. 7 illustrates a partial removal of base conductive layers, in accordance with a first removal step;

FIG. 8 illustrates a partial removal of insulation layers, in accordance with a second removal step;

FIG. 9 illustrates detachment or removal of portions of a carrier, in a detachment step;

FIG. 10 illustrates a partial removal of top layers to form upper pads, in accordance with a third removal step;

FIG. 11 illustrates an integrated circuit attached to interior pads using internal connectors, in accordance with an attachment step;

FIG. 12 illustrates an encapsulation formed over an integrated circuit and a support structure, in accordance with a molding step;

FIG. 13 is a cross-sectional view of an integrated circuit packaging system in which techniques described herein may be practiced, according to an embodiment;

FIG. 14 is a bottom view of an integrated circuit packaging system;

FIG. 15 illustrates carrier conductive layers formed directly on base conductive layers, in accordance with a second pressing step of a process flow for manufacture of a support structure with a detach carrier;

FIG. 16 illustrates a partial removal of base conductive layers and carrier conductive layers, in accordance with a first removal step;

FIG. 17 illustrates a partial removal of insulation layers through holes, in accordance with a second removal step;

FIG. 18 illustrates detachment or removal of portions of a carrier, in accordance with a detachment step;

FIG. 19 illustrates a partial removal of top layers, in accordance with a third removal step;

FIG. 20 illustrates attachment of an integrated circuit, in accordance with an attachment step;

FIG. 21 illustrates formation of an encapsulation, in accordance with a molding step;

FIG. 22 illustrates removal of a detach carrier, in accordance with a fourth removal step;

FIG. 23 is a cross-sectional view of an integrated circuit packaging system in which techniques described herein may be practiced, according to an embodiment;

FIG. 24 is a bottom view of an integrated circuit packaging system;

FIG. 25 illustrates a partial removal of base conductive layers and insulation layers, in accordance with a first removal step of a process flow for manufacture of a support structure with vias;

FIG. 26 illustrates vias formed within holes through a dielectric layer, in accordance with a filling step;

FIG. 27 illustrates detachment or removal of portions of a carrier, in accordance with a detachment step;

FIG. 28 illustrates removal of top layers, in accordance with a third removal step;

FIG. 29 illustrates attachment of an integrated circuit, in accordance with an attachment step;

FIG. 30 illustrates formation of an encapsulation, in accordance with a molding step;

FIG. 31 is a cross-sectional view of an integrated circuit packaging system in which techniques described herein may be practiced, according to an embodiment;

FIG. 32 is a bottom view of an integrated circuit packaging system;

FIG. 33 illustrates a partial removal of top layers, in accordance with a third removal step of a process flow for manufacture of a support structure with pillars on pads;

FIG. 34 illustrates attachment of an integrated circuit, in accordance with an attachment step;

FIG. 35 illustrates formation of an encapsulation, in accordance with a molding step;

FIG. 36 illustrates removal of a detach carrier, in accordance with a fourth removal step; and

FIG. 37 illustrates an example process flow, in accordance with one or more embodiments.

### DETAILED DESCRIPTION

In the following description, for the purposes of explanation, numerous specific details are set forth in order to provide a thorough understanding of the present invention. It will be apparent, however, that the present invention may be practiced without these specific details. In other instances, well-known structures and devices are shown in block diagram form in order to avoid unnecessarily obscuring the present invention.

Embodiments are described herein according to the following outline:

1.0. General Overview

2.0. Support Structure without Detach Carrier
2.1. Structural Overview
2.2. Example Manufacturing Processes

3.0. Support Structure with Detach Carrier
3.1. Structural Overview
3.2. Example Manufacturing Processes

4.0. Support Structure with Vias
4.1. Structural Overview
4.2. Example Manufacturing Processes

5.0. Support Structure with Pillars on Pads
5.1. Structural Overview
5.2. Example Manufacturing Processes

6.0. Example Manufacturing Process Flow

7.0. Example Embodiments

8.0. Extensions and Alternatives

### 1.0. General Overview

Approaches, techniques, and mechanisms are disclosed for a method of manufacturing an integrated circuit package with a single-layer substrate. In an embodiment, the inventive integrated circuit package not only reduces manufacture cost but also improves reliability and miniaturization.

According to an embodiment, a single-layer substrate is manufactured using non-photoimageable dielectric (NPID) material that is different from other dielectric materials, such as PrePreg (PPG) materials, copper clad laminates (CCL), solder resists (SR), and so forth, that are used in conventional substrates. A single-layer substrate manufactured using the NPID material provides a low cost solution by, among other aspects, eliminating certain process steps, such as a laser drill process, that are often used to manufacture the other substrates.

According to an embodiment, the NPID material utilized for the described techniques and systems may feature a low coefficient of thermal expansion (CTE), a high glass transition temperature (Tg), and/or a high modulus compared to the other dielectric materials. Such features improve reliability because of, among other aspects, improved trace protection and peel strength, thereby enhancing adhesion between traces (e.g., of copper (Cu), etc.) and dielectric materials. In an embodiment, such features also improve miniaturization because, for example, the NPID material may allow formation of traces with reduced geometry.

For existing substrates, such as single metal substrates (SMS) or 1.5-layer non-embedded trace substrates (ETS), laser drilling is typically required for via formation. The cost of laser drilling is a main cost adder in conventional substrates. Moreover, the desired fine line and spacing are typically not achievable because, for example, the traces are not embedded in these substrates. The traces also have less protection by resin as compared to embedded traces with low peel off strength of the embodiment.

### 2.0. Support Structure without Detach Carrier

2.1. Structural Overview

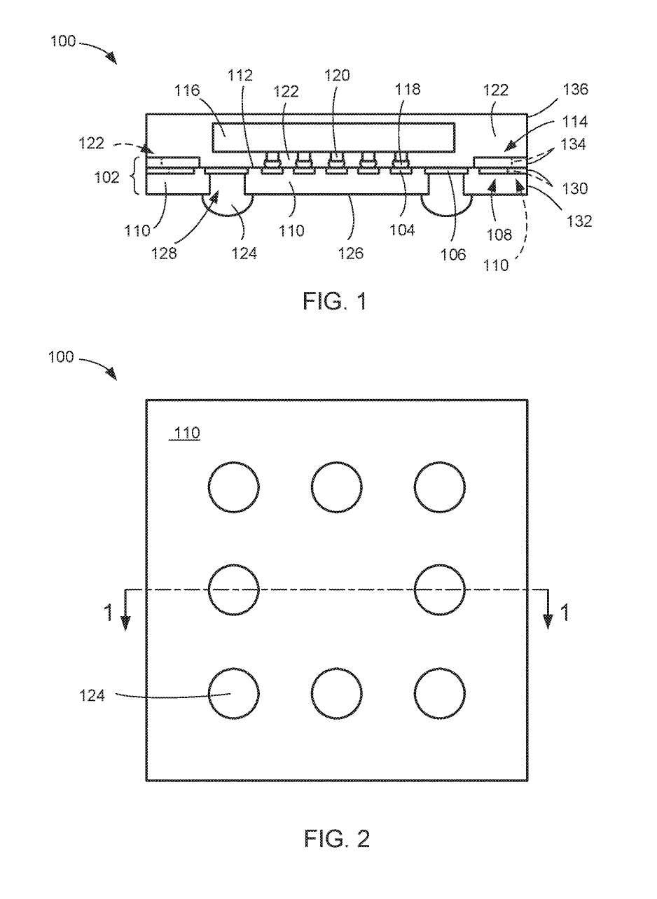

FIG. 1 is a cross-sectional view of an integrated circuit packaging system 100 in which the techniques described herein may be practiced, according to an embodiment. Integrated circuit packaging system 100 includes a support structure 102. Support structure 102 includes a number of interior pads 104, system pads 106, and exterior pads 108. Interior pads 104, system pads 106, and exterior pads 108 are structures that are used to physically attach or electrically connect to an integrated circuit or an electrical component.

Support structure 102 includes a dielectric layer 110, which is an electrical insulator. Dielectric layer 110 is formed over around interior pads 104, system pads 106, and exterior pads 108. Top surfaces of interior pads 104, system pads 106, and exterior pads 108 are exposed from dielectric layer 110. Dielectric layer 110 is directly on sidewalls of interior pads 104, system pads 106, and exterior pads 108. Dielectric layer 110 is directly on bottom surfaces of interior pads 104 and exterior pads 108. Dielectric layer 110 is partially directly on bottom surfaces of system pads 106. Top surfaces of dielectric layer 110, interior pads 104, system pads 106, and exterior pads 108 are coplanar with each other. Interior pads 104, system pads 106, and exterior pads 108 are embedded within a top portion of dielectric layer 110.

For example, dielectric layer 110 may be formed using, without limitation, a non-photoimageable dielectric (NPID), an insulation material, a dielectric film, or any other dielectric materials with predetermined physical properties. The predetermined physical properties include, without limitation, a coefficient of thermal expansion (CTE), a glass transition temperature (Tg), and/or a modulus. The predetermined physical properties will subsequently be described in more details below.

Interior pads 104, system pads 106, and exterior pads 108 are formed at a top side 112 of dielectric layer 110 of support structure 102. A number of interior pads 104 are formed immediately adjacent each other. A number of interior pads 104 are formed in a cluster at an interior area of support structure 102. A number of system pads 106 are formed around or surrounding interior pads 104. A number of interior pads 104 are directly between a system pad 106 and another system pad 106. Exterior pads 108 are formed at an exterior area of support structure 102. System pads 106 are directly in between interior pads 104 and exterior pads 108.

Support structure 102 is a single-layer support structure since support structure 102 includes only one layer, such as dielectric layer 110. For example, support structure 102 may also represent, without limitation, a substrate, a carrier, or an ETS. Support structure 102 includes upper pads 114 over top side 112 of dielectric layer 110. Upper pads 114 are directly on top side 112 of dielectric layer 110 and top sides of exterior pads 108.

Among other potential benefits, a support structure 102 having a dielectric layer 110 enhances adhesion between the dielectric layer 110 and traces (not shown), interior pads 104, system pads 106, and exterior pads 108, thereby enhancing trace and pad protection. A support structure 102 having a dielectric layer 110 may furthermore eliminate delamination of traces and pads in the support structure 102 by reducing peel strength of the traces and pads. A support structure 102 having a dielectric layer 110 that is formed without laser drilling may furthermore enable lower cost substrate.

Integrated circuit packaging system 100 includes an integrated circuit 116 and internal connectors 118. Integrated circuit 116 is a semiconductor component. For example, integrated circuit 116 may be, without limitation, an integrated circuit die, a flip-chip, or other suitable semiconductor components.

Integrated circuit 116 is mounted over support structure 102. An active side with active circuit of integrated circuit 116 is facing downwardly towards top side 112 of dielectric layer 110. Integrated circuit 116 includes contacts 120 that are electrically connected to interior pads 104. Internal connectors 118 electrically connect or physically attached to contacts 120 and interior pads 104.

Integrated circuit packaging system 100 includes an encapsulation 122, which may be, for example, an insulation cover, a package body, or a molded structure of a semiconductor package. Encapsulation 122 protects, for example, a component and electrical connectors. Encapsulation 122 covers a top side of support structure 102, integrated circuit 116, contacts 120, and internal connectors 118. Encapsulation 122 is formed directly on the top side of support structure 102, integrated circuit 116, contacts 120, internal connectors 118, interior pads 104, system pads 106, and upper pads 114.

Integrated circuit packaging system 100 includes external connectors 124. External connectors 124 are electrical connectors. For example, external connectors 124 may interconnect integrated circuit packaging system 100 and an external system (not shown), such as an electrical device. External connectors 124 are formed at a bottom side 126 of support structure 102. External connectors 124 are within holes 128 of dielectric layer 110. External connectors 124 are directly on interior sidewalls of dielectric layer 110 and bottom surfaces of system pads 106. External connectors 124 extend below bottom side 126 of support structure 102 to provide a spacing above the external system for mounting integrated circuit packaging system 100 above the external system.

Exterior pads 108 are formed outside of a chip area or a periphery of integrated circuit 116. Exterior pads 108 are formed at a periphery of support structure 102. Exterior pads 108 are electrically connected to interior pads 104 and/or system pads 106 for transmission of electrical signals between integrated circuit 116 and an external system (not shown). For example, exterior pads 108 may be part of traces or a routing layer formed on top side 112 of dielectric layer 110.

Upper pads 114 are formed above exterior pads 108. Upper pads 114 are formed at a periphery of support structure 102, among other benefits, to enhance stiffness of an edge of a strip (not of a unit) for easier handling of the strip in an assembly process. A strip is a structure with multiple units, devices, or packages that are held together before a singulation process that produces individual units, devices, or packages during manufacture. For example, upper pads 114 may be formed with a dummy or predetermined pattern to enhance the stiffness of a strip.

In an embodiment, exterior pad sidewalls 130 of exterior pads 108 may be exposed from dielectric layer 110. Exterior pad sidewalls 130 may be coplanar with a combination of dielectric sidewalls 132 of dielectric layer 110, upper pad sidewalls 134 of upper pads 114, and encapsulation sidewalls 136 of encapsulation 122. For example, exterior pad sidewalls 130 may be coplanar with dielectric sidewalls 132, upper pad sidewalls 134, and encapsulation sidewalls 136. Also, for example, exterior pad sidewalls 130 may be coplanar with dielectric sidewalls 132 and encapsulation sidewalls 136.

In an embodiment, exterior pad sidewalls 130 (e.g., as depicted using a dash line in FIG. 1) may be covered by dielectric layer 110. Dielectric layer 110 may be formed directly on exterior pad sidewalls 130. Dielectric sidewalls 132 may be coplanar with a combination of upper pad sidewalls 134 and encapsulation sidewalls 136. For example, dielectric sidewalls 132 may be coplanar with upper pad sidewalls 134 and encapsulation sidewalls 136. Also, for example, dielectric sidewalls 132 may be coplanar with encapsulation sidewalls 136.

In an embodiment, upper pad sidewalls 134 may be exposed from encapsulation 122. Upper pad sidewalls 134 may be coplanar with a combination of dielectric sidewalls 132, exterior pad sidewalls 130, and encapsulation sidewalls 136. For example, upper pad sidewalls 134 may be coplanar with dielectric sidewalls 132, exterior pad sidewalls 130, and encapsulation sidewalls 136. Also, for example, exterior pad sidewalls 130 may be coplanar with dielectric sidewalls 132 and encapsulation sidewalls 136.

In an embodiment, upper pad sidewalls 134 (e.g., as depicted using a dash line in FIG. 1) may be covered by encapsulation 122. Encapsulation 122 may be formed directly on upper pad sidewalls 134. Encapsulation sidewalls 136 may be coplanar with a combination of exterior pad sidewalls 130 and dielectric sidewalls 132. For example, encapsulation sidewalls 136 may be coplanar with exterior pad sidewalls 130 and dielectric sidewalls 132. Also, for example, encapsulation sidewalls 136 may be coplanar with dielectric sidewalls 132.

FIG. 2 is a bottom view of integrated circuit packaging system 100. Integrated circuit packaging system 100 includes dielectric layer 110 around external connectors 124. For illustrative purposes, only one row of external connectors 124 are shown on each side of integrated circuit packaging system 100 with only three external connectors 124 in each row, although it is understood that integrated circuit packaging system 100 may include any number of rows of external connectors 124 on each side of integrated circuit packaging system 100 and any number of external connectors 124 per row. Note that the view of FIG. 1 is taken along line 1-1 in FIG. 2.

2.2. Example Manufacturing Processes

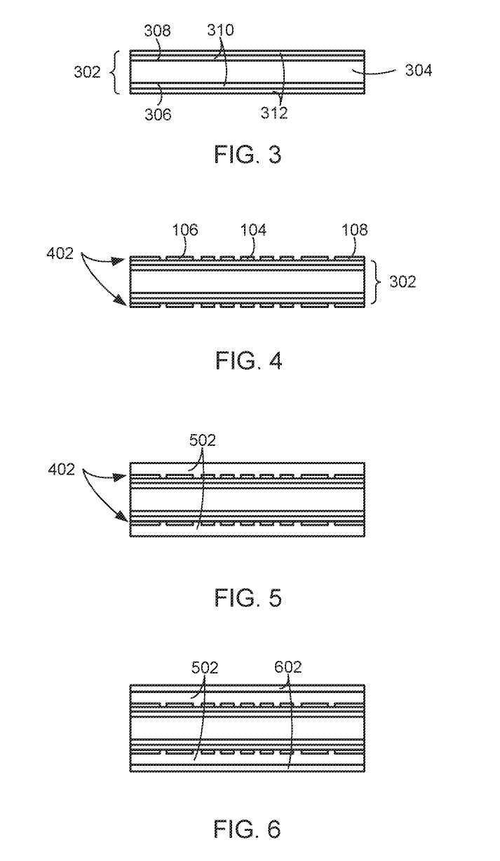

FIG. 3 is a cross-sectional view of a carrier 302 used in an initial step of a process flow for manufacture of an integrated circuit packaging system with a support structure, such as the support structure 102 of FIG. 1, without a detach carrier. For example, carrier 302 may be provided as an incoming material readily available at the beginning of the process flow. Also, for example, carrier 302 may be a copper clad laminate (CCL) or any substrate material used for integrated circuit (IC) packaging processes.

Carrier 302 includes a core layer 304 having a core bottom side 306 and a core top side 308. The carrier 302 includes intermediate layers 310 directly on core bottom side 306 and core top side 308. The carrier 302 includes top layers 312 directly on intermediate layers 310.

For example, core layer 304 may be formed with an insulation material including, without limitation, epoxy, fiberglass, or FR4 materials. Also for example, intermediate layers 310 and top layers 312 may be formed with a conductive material including, without limitation, copper (Cu), any other metallic material, or a metallic alloy.

FIG. 4 illustrates metal-one (M1) layers 402 formed directly on top layers 312, in accordance with a patterning step. The patterning step includes a metal-one (M1) patterning process. M1 layers 402 are patterned.

M1 layers 402 are patterned to form interior pads 104, system pads 106, exterior pads 108. M1 layers 402 also include traces (not shown) that are directly and electrically connect any combination of interior pads 104, system pads 106, and exterior pads 108. For example, M1 layers 402 may be patterned using one or more mask layers (not shown) such as, without limitation, dry films, photoresist layers, or dielectrics. Also, for example, M1 layers 402 may be formed with copper (Cu), a metallic material, or a metal alloy.

After M1 layers 402 are patterned, interior pads 104, system pads 106, exterior pads 108, and/or the traces include specific physical features. The physical features that are characteristic of the patterning of M1 layers 402 are on sidewalls of interior pads 104, system pads 106, exterior pads 108, and/or the traces. For example, the physical features may include, without limitation, rough surfaces, uneven surfaces, concave surfaces, removal marks, etched marks, or laser marks. Among other benefits, the physical features may provide improved adhesion for a material to form directly on a surface with the physical features. As an example, a structure of a material that has been chemically etched may have the rough surfaces, which have additional surface areas for forming another material thereon, thereby strengthening a bond between the materials. The rough surfaces are neither flat nor smooth. The rough surfaces of a structure have a texture, which is quantified by deviations in the direction of a normal vector of a real surface from its ideal form. The structure includes the rough surfaces if the deviations are greater than a predetermined threshold value of roughness.

FIG. 5 illustrates insulation layers 502 formed directly on M1 layers 402, in accordance with a lamination step. For example, insulation layers 502 may include, without limitation, a non-photoimageable dielectric (NPID), an insulation material, a dielectric film, or any other dielectric materials. Also, for example, insulation layers 502 may be formed with a dielectric material that is different from other dielectric materials including, without limitation, a PrePreg (PPG) material, a copper clad laminate (CCL), or a solder resist (SR). As another example, in an embodiment, insulation layers 502 do not include glass that is included in CCL.

Insulation layers 502 include predetermined physical properties, as mentioned previously. The predetermined physical properties may include, without limitation, a coefficient of thermal expansion (CTE), a glass transition temperature (Tg), and/or a modulus. The coefficient of thermal expansion (CTE), the glass transition temperature (Tg), and the modulus may be measured using parts-per-millions (ppm) or parts-per-millions per degree Celsius (ppm/° C.), degree Celsius (° C.), and gigapascals (Gpa), respectively.

The CTE is a tendency of matter to change in shape, area, or volume in response to a change in temperature (e.g., through heat transfer, etc.). For example, the CTE may be a fractional increase in a length per unit rise in temperature.

The Tg of a material characterizes a range of temperatures over which a glass transition occurs. For example, the Tg may be lower than a melting temperature (Tm) of a crystalline state of a material.

The modulus (e.g., Young's modulus, etc.) may be an elastic modulus, which is a mechanical property of a linear elastic solid material. A modulus may be determined using a relationship between stress (force per unit area) and strain (proportional deformation) in a material. For example, a modulus may be a Young's modulus, which is a ratio of stress in units of pressure to strain, which is dimensionless.

For example, insulation layers 502 may include a CTE having an approximate range from 0 ppm to 30 ppm. As an example, insulation layers 502 may include a CTE of 13 ppm, compared to CCL having a CTE of 5 ppm and SR having a CTE of 60 ppm. Thus, insulation layers 502 may have a low CTE compared to other dielectric materials (e.g., SR, etc.).

For example, insulation layers 502 may include a Tg having an approximate range from 200° C. to 350° C. As an example, insulation layers 502 may include a Tg of 280° C., compared to CCL having a Tg of 280° C. and SR having a Tg of 100° C. Thus, insulation layers 502 may have a high Tg compared to other dielectric materials (e.g., SR, etc.).

For example, insulation layers 502 may include a modulus having an approximate range from 5 Gpa to 30 Gpa. As an example, insulation layers 502 may include a modulus of 15 Gpa, compared to CCL having a modulus of 32 Gpa and SR having a modulus of 3 Gpa. Thus, insulation layers 502 may have a high modulus compared to other dielectric materials (e.g., SR, etc.).

FIG. 6 illustrates base conductive layers 602 formed directly on insulation layers 502, in accordance with a pressing step. For example, the pressing step may include a hot press method, any other pressing method, and so forth. For example, base conductive layers 602 may include copper (Cu), any other metallic material, or a metal alloy.

For example, the pressing step may employ heat and a device for applying a pressure to base conductive layers 602 in order to bond base conductive layers 602 to insulation layers 502 to form a base carrier. A temperature of the device may be at least slightly greater than a melting temperature of base conductive layers 602. The heat and the pressure applied by the device may cause base conductive layers 602 to flow and subsequently solidify in bonded contact with insulation layers 502.

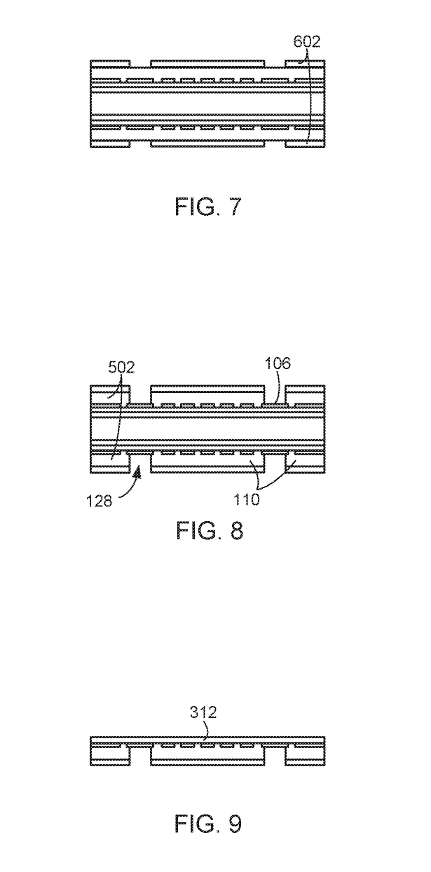

FIG. 7 illustrates the partial removal of base conductive layers 602, in accordance with a first removal step. For example, the first removal step may employ chemical etching or any other chemical and mechanical removal method.

FIG. 8 illustrates the partial removal of insulation layers 502, in accordance with a second removal step. Holes 128 through insulation layers 502 are formed when insulation layers 502 are partially removed. Holes 128 are formed through insulation layers 502. Holes 128 expose system pads 106. Insulation layers 502 having holes 128 form dielectric layer 110.

For example, the second removal step may employ chemical etching or any other chemical and mechanical removal method. In an embodiment, the second removal step does not form dielectric layer 110 using photolithography, or any other method using light or laser.

In an embodiment, dielectric layer 110 For illustrative purposes, only one structure is shown by M1 layers 402 of FIG. 4 to have fine line and space dimensions. For example, the traces may have a line or wire width of less than 20 micrometers (um). Also, for example, the traces may have a line space of less than 20 um between lines or wires. Among other potential benefits, dielectric layer 110 may improve miniaturization because dielectric layer 110 may allow formation of traces with reduced geometry or fine line and spacing dimensions.

After insulation layers 502 are partially removed, dielectric layer 110 and system pads 106 include specific physical features. The physical features that are characteristic of the partial removal of insulation layers 502 are on interior sidewalls in holes 128 of dielectric layer 110 and bottom surfaces of system pads 106. For example, the physical features may include, without limitation, rough surfaces, uneven surfaces, concave surfaces, removal marks, etched marks, or laser marks. Among other benefits, the physical features may provide improved adhesion for a material to form directly on a surface with the physical features. As an example, a structure of a material that has been chemically etched may have a rough surface, which has additional surface areas for forming another material thereon, thereby strengthening a bond between the materials. The rough surfaces are neither flat nor smooth. The rough surfaces of a structure have a texture, which is quantified by deviations in the direction of a normal vector of a real surface from its ideal form. The structure includes the rough surfaces if the deviations are greater than a predetermined threshold value of roughness.

FIG. 9 illustrates detachment or removal of portions of carrier 302, in a detachment step. The portions of carrier 302 removed include core layer 304 of FIG. 3 and intermediate layers 310 of FIG. 3, leaving top layers 312 as shown in the structure of FIG. 9.

For illustrative purposes, only one structure is shown in FIG. 9, although there may in fact be two of these structures after the detachment step completes. Among other benefits, this may allow for double-side substrate manufacturing, resulting in two times production capability per one-time manufacturing.

After intermediate layers 310 are removed, top layers 312 include specific physical features. The physical features that are characteristic of the removal of intermediate layers 310 are on top surfaces of top layers 312, which are subsequently used to form upper pads 114 of FIG. 1. For example, the physical features may include, without limitation, rough surfaces, uneven surfaces, concave surfaces, removal marks, etched marks, or laser marks. Among other benefits, the physical features may provide improved adhesion for a material to form directly on a surface with the physical features. As an example, a structure of a material that has been chemically etched may have a rough surface, which has additional surface areas for forming another material thereon, thereby strengthening a bond between the materials. The rough surfaces are neither flat nor smooth. The rough surfaces of a structure have a texture, which is quantified by deviations in the direction of a normal vector of a real surface from its ideal form. The structure includes the rough surfaces if the deviations are greater than a predetermined threshold value of roughness.

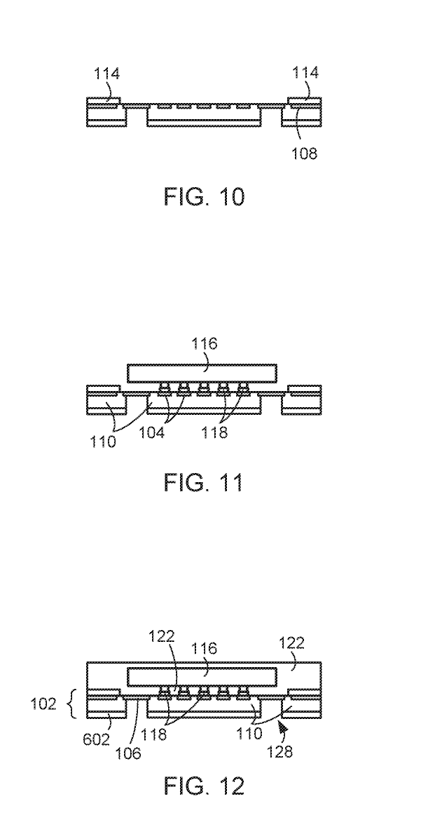

FIG. 10 illustrates the partial removal of top layers 312 to form upper pads 114, in accordance with a third removal step. For example, the third removal step may employ chemical etching or any other chemical and mechanical removal method.

For illustrative purposes, upper pads 114 are shown to have a width greater than a width of exterior pads 108, although it is understood that upper pads 114 may be formed in different manners. For example, upper pads 114 may instead have a width equal to or less than a width of exterior pads 108.

After top layers 312 are partially removed, upper pads 114 include specific physical features. The physical features that are characteristic of the partially removal of top layers 312 are on sidewalls of upper pads 114. For example, the physical features may include, without limitation, rough surfaces, uneven surfaces, concave surfaces, removal marks, etched marks, or laser marks. Among other benefits, the physical features may provide improved adhesion for a material to form directly on a surface with the physical features. As an example, a structure of a material that has been chemically etched may have a rough surface, which has additional surface areas for forming another material thereon, thereby strengthening a bond between the materials. The rough surfaces are neither flat nor smooth. The rough surfaces of a structure have a texture, which is quantified by deviations in the direction of a normal vector of a real surface from its ideal form. The structure includes the rough surfaces if the deviations are greater than a predetermined threshold value of roughness.

FIG. 11 illustrates integrated circuit 116 attached to interior pads 104 using internal connectors 118, in accordance with an attachment step. Integrated circuit 116 is mounted over dielectric layer 110. Integrated circuit 116 is directly over interior pads 104. For example, integrated circuit 116 may be mounted using a jig, a pick and place equipment, any other assembly device, or any other mounting mechanism.

FIG. 12 illustrates encapsulation 122 formed over integrated circuit 116 and support structure 102, in accordance with a molding step. For example, encapsulation 122 may be formed using a molded underfill (MUF), or any molding material. Encapsulation 122 is between support structure 102 and integrated circuit 116. Encapsulation 122 is under integrated circuit 116 and around internal connectors 118. Encapsulation 122 is directly on a portion of dielectric layer 110.

After completion of the molding step, the manufacturing process continues with a second attachment step. In the second attachment step, base conductive layers 602 are removed. Dielectric layer 110 is exposed after base conductive layers 602 are removed. For example, base conductive layers 602 may be removed by employing chemical etching, or any other chemical and mechanical removal method.

After base conductive layers 602 are removed, dielectric layer 110 include specific physical features. The physical features that are characteristic of the removal of base conductive layers 602 are on a bottom surface of dielectric layer 110. For example, the physical features may include, without limitation, rough surfaces, uneven surfaces, concave surfaces, removal marks, etched marks, or laser marks. Among other benefits, the physical features may provide improved adhesion for a material to form directly on a surface with the physical features. As an example, a structure of a material that has been chemically etched may have a rough surface, which has additional surface areas for forming another material thereon, thereby strengthening a bond between the materials. The rough surfaces are neither flat nor smooth. The rough surfaces of a structure have a texture, which is quantified by deviations in the direction of a normal vector of a real surface from its ideal form. The structure includes the rough surfaces if the deviations are greater than a predetermined threshold value of roughness.

The second attachment step attaches external connectors 124 of FIG. 1. External connectors 124 are attached to or directly on system pads 106. External connectors 124 are within holes 128. For example, external connectors 124 may be attached using a solder ball mount (SBM) method or any other mounting method. Also, for example, external connectors 124 may be formed using solder, a metallic material, or a metal alloy.

### 3.0. Support Structure with Detach Carrier

3.1. Structural Overview

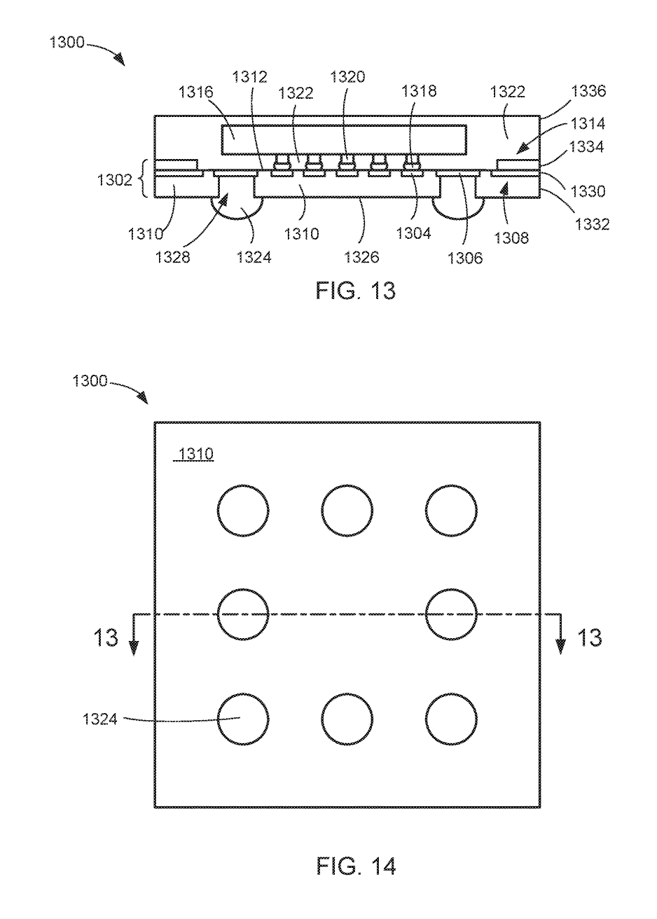

FIG. 13 is a cross-sectional view of an integrated circuit packaging system 1300 in which the techniques described herein may be practiced, according to an embodiment. Integrated circuit packaging system 1300 includes a support structure 1302. Support structure 1302 includes a number of interior pads 1304, system pads 1306, and exterior pads 1308. Interior pads 1304, system pads 1306, and exterior pads 1308 are structures that are used to physically attach or electrically connect to an integrated circuit or an electrical component.

Support structure 1302 includes a dielectric layer 1310, which is an electrical insulator. Dielectric layer 1310 is formed over around interior pads 1304, system pads 1306, and exterior pads 1308. Top surfaces of interior pads 1304, system pads 1306, and exterior pads 1308 are exposed from dielectric layer 1310. Dielectric layer 1310 is directly on sidewalls of interior pads 1304, system pads 1306, and exterior pads 1308. Dielectric layer 1310 is directly on bottom surfaces of interior pads 1304 and exterior pads 1308. Dielectric layer 1310 is partially directly on bottom surfaces of system pads 1306. Top surfaces of dielectric layer 1310, interior pads 1304, system pads 1306, and exterior pads 1308 are coplanar with each other. Interior pads 1304, system pads 1306, and exterior pads 1308 are embedded within a top portion of dielectric layer 1310.

For example, dielectric layer 1310 may be formed using, without limitation, a non-photoimageable dielectric (NPID), an insulation material, a dielectric film, or any other dielectric materials with predetermined physical properties. The predetermined physical properties include, without limitation, a coefficient of thermal expansion (CTE), a glass transition temperature (Tg), and/or a modulus. The predetermined physical properties have been described in details above.

Interior pads 1304, system pads 1306, and exterior pads 1308 are formed at a top side 1312 of dielectric layer 1310 of support structure 1302. A number of interior pads 1304 are formed immediately adjacent each other. A number of interior pads 1304 are formed in a cluster at an interior area of support structure 1302. A number of system pads 1306 are formed around or surrounding interior pads 1304. A number of interior pads 1304 are directly between a system pad 1306 and another system pad 1306. Exterior pads 1308 are formed at an exterior area of support structure 1302. System pads 1306 are directly in between interior pads 1304 and exterior pads 1308.

Support structure 1302 is a single-layer support structure since support structure 1302 includes only one layer, such as dielectric layer 1310. For example, support structure 1302 may also represent, without limitation, a substrate, a carrier, or an ETS. Support structure 1302 includes upper pads 1314 over top side 1312 of dielectric layer 1310. Upper pads 1314 are directly on top side 1312 of dielectric layer 1310 and top sides of exterior pads 1308.

Among other potential benefits, a support structure 1302 having a dielectric layer 1310 enhances adhesion between the dielectric layer 1310 and traces (not shown), interior pads 1304, system pads 1306, and exterior pads 1308, thereby enhancing trace and pad protection. A support structure 1302 having a dielectric layer 1310 may furthermore eliminate delamination of traces and pads in the support structure 1302 by reducing peel strength of the traces and pads. A support structure 1302 having a dielectric layer 1310 that is formed without laser drilling may furthermore enable lower cost substrate.

Integrated circuit packaging system 1300 includes an integrated circuit 1316 and internal connectors 1318. Integrated circuit 1316 is a semiconductor component. For example, integrated circuit 1316 may be, without limitation, an integrated circuit die, a flip-chip, or other suitable semiconductor components.

Integrated circuit 1316 is mounted over support structure 1302. An active side with active circuit of integrated circuit 1316 is facing downwardly towards top side 1312 of dielectric layer 1310. Integrated circuit 1316 includes contacts 1320 that are electrically connected to interior pads 1304. Internal connectors 1318 electrically connect or physically attached to contacts 1320 and interior pads 1304.

Integrated circuit packaging system 1300 includes an encapsulation 1322, which may be, for example, an insulation cover, a package body, or a molded structure of a semiconductor package. Encapsulation 1322 protects, for example, a component and electrical connectors. Encapsulation 1322 covers a top side of support structure 1302, integrated circuit 1316, contacts 1320, and internal connectors 1318. Encapsulation 1322 is formed directly on the top side of support structure 1302, integrated circuit 1316, contacts 1320, internal connectors 1318, interior pads 1304, system pads 1306, and upper pads 1314.

Integrated circuit packaging system 1300 includes external connectors 1324. External connectors 1324 are electrical connectors. For example, external connectors 1324 may interconnect integrated circuit packaging system 1300 and an external system (not shown), such as an electrical device. External connectors 1324 are formed at a bottom side 1326 of support structure 1302. External connectors 1324 are within holes 1328 of dielectric layer 1310. External connectors 1324 are directly on interior sidewalls of dielectric layer 1310 and bottom surfaces of system pads 1306. External connectors 1324 extend below bottom side 1326 of support structure 1302 to provide a spacing above the external system for mounting integrated circuit packaging system 1300 above the external system.

In an embodiment, exterior pad sidewalls 1330 of exterior pads 1308 may be exposed from dielectric layer 1310. Exterior pad sidewalls 1330 may be coplanar with a combination of dielectric sidewalls 1332 of dielectric layer 1310, upper pad sidewalls 1334 of upper pads 1314, and encapsulation sidewalls 1336 of encapsulation 1322. For example, exterior pad sidewalls 1330 may be coplanar with dielectric sidewalls 1332, upper pad sidewalls 1334, and encapsulation sidewalls 1336. Also, for example, exterior pad sidewalls 1330 may be coplanar with dielectric sidewalls 1332 and encapsulation sidewalls 1336.

In an embodiment, upper pad sidewalls 1334 may be exposed from encapsulation 1322. Upper pad sidewalls 1334 may be coplanar with a combination of dielectric sidewalls 1332, exterior pad sidewalls 1330, and encapsulation sidewalls 1336. For example, upper pad sidewalls 1334 may be coplanar with dielectric sidewalls 1332, exterior pad sidewalls 1330, and encapsulation sidewalls 1336. Also, for example, exterior pad sidewalls 1330 may be coplanar with dielectric sidewalls 1332 and encapsulation sidewalls 1336.

For illustrative purposes, exterior pad sidewalls 1330 and upper pad sidewalls 1334 are coplanar with dielectric sidewalls 1332 and encapsulation sidewalls 1336, although it is understood that exterior pad sidewalls 1330 and upper pad sidewalls 1334 may be formed in a different manner. For example, exterior pad sidewalls 1330 and upper pad sidewalls 1334 may be covered by dielectric layer 1310 and encapsulation 1322, respectively.

FIG. 14 is a bottom view of integrated circuit packaging system 1300. Integrated circuit packaging system 1300 includes dielectric layer 1310 around external connectors 1324. For illustrative purposes, only one row of external connectors 1324 are shown on each side of integrated circuit packaging system 1300 with only three external connectors 1324 in each row, although it is understood that integrated circuit packaging system 1300 may include any number of rows of external connectors 1324 on each side of integrated circuit packaging system 1300 and any number of external connectors 1324 per row. Note that the view of FIG. 13 is taken along line 13-13 in FIG. 14.

3.2. Example Manufacturing Processes

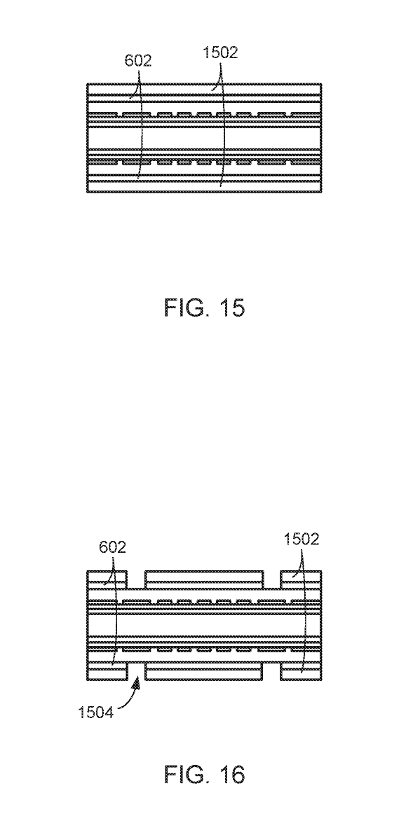

FIG. 15 illustrates carrier conductive layers 1502 formed directly on base conductive layers 602, in accordance with a second pressing step of a process flow for manufacture of a support structure, such as the support structure 1302 of FIG. 13, with a detach carrier. The process flow includes the method steps described above in FIGS. 3-6. For example, the second pressing step may include a hot press method, or any other pressing method. The second pressing step forms carrier conductive layers 1502 directly on base conductive layers 602. For example, carrier conductive layers 1502 may include, without limitation, copper (Cu), any metallic material, or a metal alloy.

For example, the second pressing step may employ heat and a device for applying a pressure to carrier conductive layers 1502 in order to bond carrier conductive layers 1502 to base conductive layers 602 to form a detach carrier. A temperature of the device may be at least slightly greater than a melting temperature of carrier conductive layers 1502. The heat and the pressure applied by the device may cause carrier conductive layers 1502 to flow and subsequently solidify in bonded contact with base conductive layers 602.

FIG. 16 illustrates the partial removal of base conductive layers 602 and carrier conductive layers 1502, in accordance with a first removal step. The first removal step is employed to perform a double-layer removal method. Holes 1504 are formed through base conductive layers 602 and carrier conductive layers 1502 when base conductive layers 602 and carrier conductive layers 1502 are partially removed. For example, the first removal step may employ chemical etching or any other chemical and mechanical removal method.

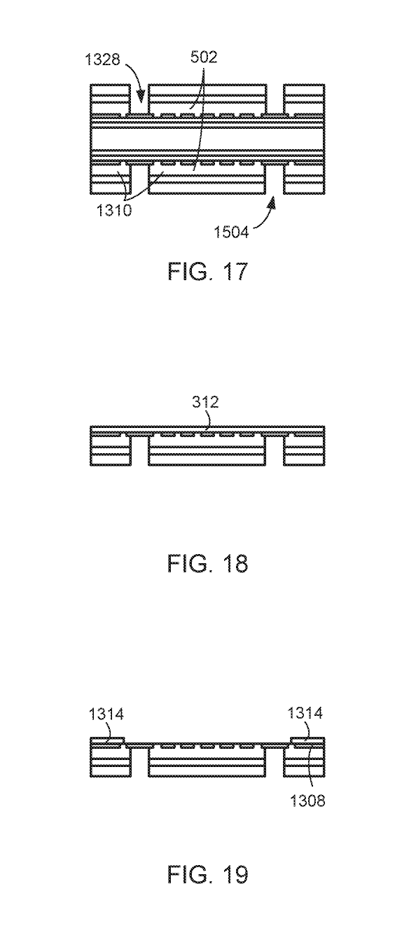

FIG. 17 illustrates the partial removal of insulation layers 502 through holes 1504, in accordance with a second removal step. Holes 1328 are formed through insulation layers 502 when insulation layers 502 are partially removed. Holes 1328 expose system pads 1306. Insulation layers 502 having holes 1328 form dielectric layer 1310.

For example, the second removal step may employ chemical etching or any other chemical and mechanical removal method. In an embodiment, the second removal step does not form dielectric layer 1310 using photolithography, or any other method using light or laser.

After insulation layers 502 are partially removed, dielectric layer 1310 and system pads 1306 include specific physical features. The physical features that are characteristic of the partial removal of insulation layers 502 are on interior sidewalls in holes 1328 of dielectric layer 1310 and bottom surfaces of system pads 106. For example, the physical features may include, without limitation, rough surfaces, uneven surfaces, concave surfaces, removal marks, etched marks, or laser marks. Among other benefits, the physical features may provide improved adhesion for a material to form directly on a surface with the physical features. As an example, a structure of a material that has been chemically etched may have a rough surface, which has additional surface areas for forming another material thereon, thereby strengthening a bond between the materials. The rough surfaces are neither flat nor smooth. The rough surfaces of a structure have a texture, which is quantified by deviations in the direction of a normal vector of a real surface from its ideal form. The structure includes the rough surfaces if the deviations are greater than a predetermined threshold value of roughness.

In an embodiment, dielectric layer 1310 allows traces (not shown) formed by M1 layers 402 of FIG. 4 to have fine line and space dimensions. For example, the traces may have a line or wire width of less than 20 micrometers (um). Also, for example, the traces may have a line space of less than 20 um between lines or wires. Among other potential benefits, dielectric layer 1310 may improve miniaturization because dielectric layer 1310 may allow formation of traces with reduced geometry or fine line and spacing dimensions.

FIG. 18 illustrates detachment or removal of portions of carrier 302, in accordance with a detachment step. The portions of carrier 302 removed include core layer 304 of FIG. 3 and intermediate layers 310 of FIG. 3, leaving top layers 312 as shown in the structure of FIG. 9.

After intermediate layers 310 are removed, top layers 312 include specific physical features. The physical features that are characteristic of the removal of intermediate layers 310 are on top surfaces of top layers 312, which are subsequently used to form upper pads 1314 of FIG. 1. For example, the physical features may include, without limitation, rough surfaces, uneven surfaces, concave surfaces, removal marks, etched marks, or laser marks. Among other benefits, the physical features may provide improved adhesion for a material to form directly on a surface with the physical features. As an example, a structure of a material that has been chemically etched may have a rough surface, which has additional surface areas for forming another material thereon, thereby strengthening a bond between the materials. The rough surfaces are neither flat nor smooth. The rough surfaces of a structure have a texture, which is quantified by deviations in the direction of a normal vector of a real surface from its ideal form. The structure includes the rough surfaces if the deviations are greater than a predetermined threshold value of roughness.

For illustrative purposes, only one structure is shown in FIG. 18, although there may in fact be two of these structures after the detachment step completes. Among other benefits, this may allow for double-side substrate manufacturing, resulting in two times production capability per one-time manufacturing.

FIG. 19 illustrates the partial removal of top layers 312, in accordance with a third removal step. Top layers 312 are partially removed to form upper pads 1314. For example, the third removal step may employ chemical etching or any other chemical and mechanical removal method.

After top layers 312 are partially removed, upper pads 1314 include specific physical features. The physical features that are characteristic of the partially removal of top layers 312 are on sidewalls of upper pads 1314. For example, the physical features may include, without limitation, rough surfaces, uneven surfaces, concave surfaces, removal marks, etched marks, or laser marks. Among other benefits, the physical features may provide improved adhesion for a material to form directly on a surface with the physical features. As an example, a structure of a material that has been chemically etched may have a rough surface, which has additional surface areas for forming another material thereon, thereby strengthening a bond between the materials. The rough surfaces are neither flat nor smooth. The rough surfaces of a structure have a texture, which is quantified by deviations in the direction of a normal vector of a real surface from its ideal form. The structure includes the rough surfaces if the deviations are greater than a predetermined threshold value of roughness.

For illustrative purposes, upper pads 1314 are shown to have a width greater than a width of exterior pads 1308, although it is understood that upper pads 1314 may be formed in different manners. For example, upper pads 1314 may instead have a width equal to or less than a width of exterior pads 1308.

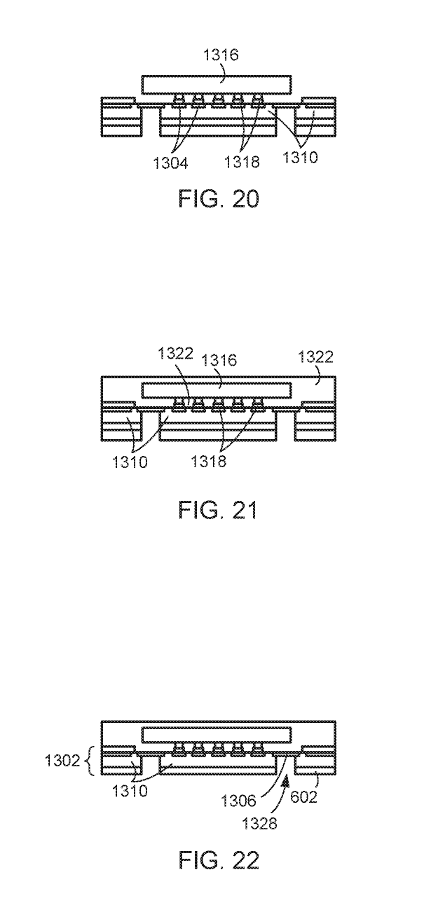

FIG. 20 illustrates attachment of integrated circuit 1316, in accordance with an attachment step. Integrated circuit 1316 is attached to interior pads 1304 using internal connectors 1318. Integrated circuit 1316 is mounted over dielectric layer 1310. Integrated circuit 1316 is directly over interior pads 1304. For example, integrated circuit 1316 may be mounted using a jig, a pick and place equipment, any other assembly device, or any other mounting mechanism.

FIG. 21 illustrates formation of encapsulation 1322, in accordance with a molding step. Encapsulation 1322 is formed over integrated circuit 1316. For example, encapsulation 1322 may be formed using a molded underfill (MUF), or any molding material. Encapsulation 1322 is under integrated circuit 1316 and around internal connectors 1318. Encapsulation 1322 is directly on a portion of dielectric layer 1310.

FIG. 22 illustrates removal of the detach carrier, in accordance with a fourth removal step. The fourth removal step removes carrier conductive layers 1502 of FIG. 15. Base conductive layers 602 are exposed after carrier conductive layers 1502 are removed. For example, carrier conductive layers 1502 may be removed by employing chemical etching, or any other chemical and mechanical removal method.

After completion of the fourth removal step, the manufacturing process continues with a second attachment step. In the second attachment step, base conductive layers 602 are removed. Dielectric layer 1310 is exposed after base conductive layers 602 are removed. For example, base conductive layers 602 may be removed by employing chemical etching, or any other chemical and mechanical removal method.

After base conductive layers 602 are removed, dielectric layer 1310 include specific physical features. The physical features that are characteristic of the removal of base conductive layers 602 are on a bottom surface of dielectric layer 1310. For example, the physical features may include, without limitation, rough surfaces, uneven surfaces, concave surfaces, removal marks, etched marks, or laser marks. Among other benefits, the physical features may provide improved adhesion for a material to form directly on a surface with the physical features. As an example, a structure of a material that has been chemically etched may have a rough surface, which has additional surface areas for forming another material thereon, thereby strengthening a bond between the materials. The rough surfaces are neither flat nor smooth. The rough surfaces of a structure have a texture, which is quantified by deviations in the direction of a normal vector of a real surface from its ideal form. The structure includes the rough surfaces if the deviations are greater than a predetermined threshold value of roughness.

The second attachment step attaches external connectors 1324 of FIG. 1. External connectors 1324 are attached to or directly on system pads 1306. External connectors 1324 are within holes 1328. For example, external connectors 1324 may be attached using a solder ball mount (SBM) method or any other mounting method. Also, for example, external connectors 1324 may be formed using solder, a metallic material, or a metal alloy.

### 4.0. Support Structure with Vias

4.1. Structural Overview

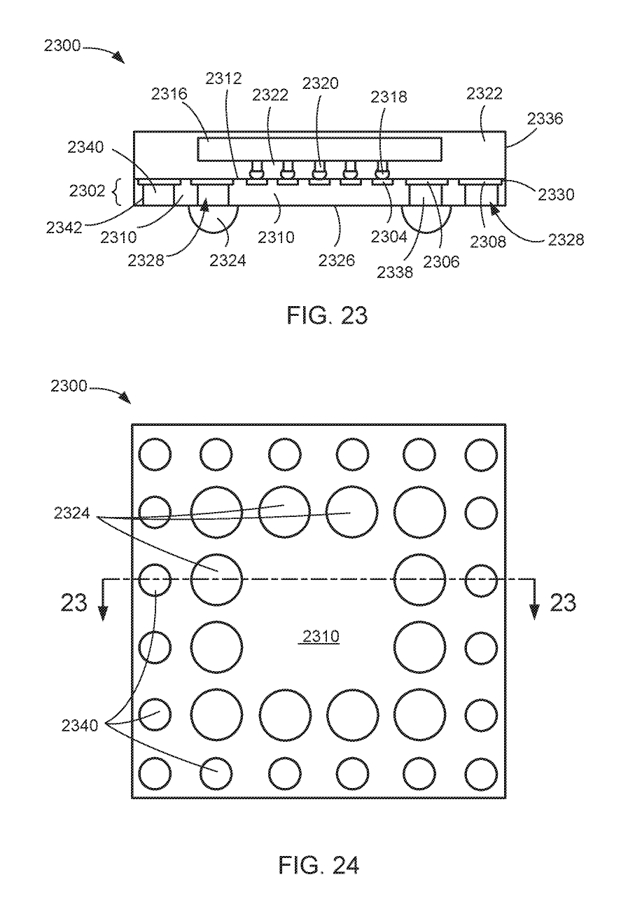

FIG. 23 is a cross-sectional view of an integrated circuit packaging system 2300 in which the techniques described herein may be practiced, according to an embodiment. Integrated circuit packaging system 2300 includes a support structure 2302. Support structure 2302 includes a number of interior pads 2304, system pads 2306, and exterior pads 2308. Interior pads 2304, system pads 2306, and exterior pads 2308 are structures that are used to physically attach or electrically connect to an integrated circuit or an electrical component.

Support structure 2302 includes a dielectric layer 2310, which is an electrical insulator. Dielectric layer 2310 is formed over around interior pads 2304, system pads 2306, and exterior pads 2308. Top surfaces of interior pads 2304, system pads 2306, and exterior pads 2308 are exposed from dielectric layer 2310. Dielectric layer 2310 is directly on sidewalls of interior pads 2304, system pads 2306, and exterior pads 2308. Dielectric layer 2310 is directly on bottom surfaces of interior pads 2304 and exterior pads 2308. Dielectric layer 2310 is partially directly on bottom surfaces of system pads 2306. Top surfaces of dielectric layer 2310, interior pads 2304, system pads 2306, and exterior pads 2308 are coplanar with each other. Interior pads 2304, system pads 2306, and exterior pads 2308 are embedded within a top portion of dielectric layer 2310.

For example, dielectric layer 2310 may be formed using, without limitation, a non-photoimageable dielectric (NPID), an insulation material, a dielectric film, or any other dielectric materials with predetermined physical properties. The predetermined physical properties include, without limitation, a coefficient of thermal expansion (CTE), a glass transition temperature (Tg), and/or a modulus. The predetermined physical properties have been described in details above.

Interior pads 2304, system pads 2306, and exterior pads 2308 are formed at a top side 2312 of dielectric layer 2310 of support structure 2302. A number of interior pads 2304 are formed immediately adjacent each other. A number of interior pads 2304 are formed in a cluster at an interior area of support structure 2302. A number of system pads 2306 are formed around or surrounding interior pads 2304. A number of interior pads 2304 are directly between a system pad 2306 and another system pad 2306. Exterior pads 2308 are formed at an exterior area of support structure 2302. System pads 2306 are directly in between interior pads 2304 and exterior pads 2308.

Support structure 2302 is a single-layer support structure since support structure 2302 includes only one layer, such as dielectric layer 2310. For example, support structure 2302 may also represent, without limitation, a substrate, a carrier, or an ETS.

Among other potential benefits, a support structure 2302 having a dielectric layer 2310 enhances adhesion between the dielectric layer 2310 and traces (not shown), interior pads 2304, system pads 2306, and exterior pads 2308, thereby enhancing trace and pad protection. A support structure 2302 having a dielectric layer 2310 may furthermore eliminate delamination of traces and pads in the support structure 2302 by reducing peel strength of the traces and pads. A support structure 2302 having a dielectric layer 2310 that is formed without laser drilling may furthermore enable lower cost substrate.

Integrated circuit packaging system 2300 includes an integrated circuit 2316 and internal connectors 2318. Integrated circuit 2316 is a semiconductor component. For example, integrated circuit 2316 may be, without limitation, an integrated circuit die, a flip-chip, or other suitable semiconductor components.

Integrated circuit 2316 is mounted over support structure 2302. An active side with active circuit of integrated circuit 2316 is facing downwardly towards top side 2312 of dielectric layer 2310. Integrated circuit 2316 includes contacts 2320 that are electrically connected to interior pads 2304. Internal connectors 2318 electrically connect or physically attached to contacts 2320 and interior pads 2304.

Integrated circuit packaging system 2300 includes an encapsulation 2322, which may be, for example, an insulation cover, a package body, or a molded structure of a semiconductor package. Encapsulation 2322 protects, for example, a component and electrical connectors. Encapsulation 2322 covers a top side of support structure 2302, integrated circuit 2316, contacts 2320, and internal connectors 2318. Encapsulation 2322 is formed directly on the top side of support structure 2302, integrated circuit 2316, contacts 2320, internal connectors 2318, interior pads 2304, and system pads 2306.

Integrated circuit packaging system 2300 includes external connectors 2324. External connectors 2324 are electrical connectors. For example, external connectors 2324 may interconnect integrated circuit packaging system 2300 and an external system (not shown), such as an electrical device. External connectors 2324 are formed at a bottom side 2326 of support structure 2302. External connectors 2324 are attached to interior pillars 2338 of support structure 2302. External connectors 2324 are directly on bottom surfaces of dielectric layer 2310 and interior pillars 2338. External connectors 2324 extend below bottom side 2326 of support structure 2302 to provide a spacing above the external system for mounting integrated circuit packaging system 2300 above the external system.

Interior pillars 2338 are electrical connectors. Interior pillars 2338 are formed within holes 2328 at an interior area of dielectric layer 2310. Interior pillars 2338 are directly on interior sidewalls of dielectric layer 2310 and bottom surfaces of system pads 2306.

Exterior pillars 2340 of support structure 2302 are electrical connectors. Exterior pillars 2340 are formed within holes 2328 at an exterior area of dielectric layer 2310. Exterior pillars 2340 directly on interior sidewalls of dielectric layer 2310 and bottom surfaces of exterior pads 2308.

Exterior pad sidewalls 2330 are covered by dielectric layer 2310. Pillar sidewalls 2342 of exterior pillars 2340 are covered by dielectric layer 2310. Encapsulation sidewalls 2336 are coplanar with exterior sidewalls of dielectric layer 2310.

FIG. 24 is a bottom view of integrated circuit packaging system 2300. Integrated circuit packaging system 2300 includes dielectric layer 2310 around external connectors 2324 and exterior pillars 2340. For illustrative purposes, only one row of external connectors 2324 and one row of exterior pillars 2340 are shown on each side of integrated circuit packaging system 2300, although it is understood that integrated circuit packaging system 1300 may include any number of rows of external connectors 2324 and exterior pillars 2340 on each side of integrated circuit packaging system 2300 and any number of external connectors 2324 and exterior pillars 2340 per row. Note that the view of FIG. 23 is taken along line 23-23 in FIG. 24.

4.2. Example Manufacturing Processes

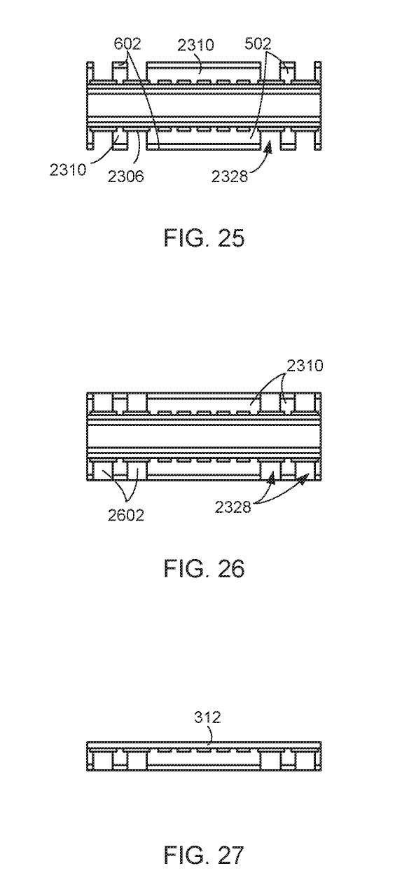

FIG. 25 illustrates the partial removal of base conductive layers 602 and insulation layers 502, in accordance with a first removal step of a process flow for manufacture of a support structure, such as the support structure 2302 of FIG. 23, with vias. The process flow includes the method steps described above in FIGS. 3-6.

Holes 2328 through insulation layers 502 are formed when insulation layers 502 are partially removed. Holes 2328 are formed through insulation layers 502. Holes 2328 expose system pads 2306. Insulation layers 502 having holes 2328 form dielectric layer 2310.

For example, the first removal step may employ chemical etching or any other chemical and mechanical removal method. In an embodiment, the first removal step does not form dielectric layer 2310 using photolithography, or any other method using light or laser.

After insulation layers 502 are partially removed, dielectric layer 2310 and system pads 2306 include specific physical features. The physical features that are characteristic of the partial removal of insulation layers 502 are on interior sidewalls in holes 2328 of dielectric layer 2310 and bottom surfaces of system pads 2306. For example, the physical features may include, without limitation, rough surfaces, uneven surfaces, concave surfaces, removal marks, etched marks, or laser marks. Among other benefits, the physical features may provide improved adhesion for a material to form directly on a surface with the physical features. As an example, a structure of a material that has been chemically etched may have a rough surface, which has additional surface areas for forming another material thereon, thereby strengthening a bond between the materials. The rough surfaces are neither flat nor smooth. The rough surfaces of a structure have a texture, which is quantified by deviations in the direction of a normal vector of a real surface from its ideal form. The structure includes the rough surfaces if the deviations are greater than a predetermined threshold value of roughness.

In an embodiment, dielectric layer 2310 allows traces (not shown) formed by M1 layers 402 of FIG. 4 to have fine line and space dimensions. For example, the traces may have a line or wire width of less than 20 micrometers (um). Also, for example, the traces may have a line space of less than 20 um between lines or wires. Among other potential benefits, dielectric layer 2310 may improve miniaturization because dielectric layer 2310 may allow formation of traces with reduced geometry or fine line and spacing dimensions.

FIG. 26 illustrates additional vias 2602 formed within holes 2328 through dielectric layer 2310, in accordance with a filling step. Vias 2602 are electrical conductors. For example, vias 2602 may be formed using copper (Cu), any metallic material, or a metal alloy.

FIG. 27 illustrates detachment or removal of portions of carrier 302, in accordance with a detachment step. The portions of carrier 302 removed include core layer 304 of FIG. 3 and intermediate layers 310 of FIG. 3, leaving top layers 312 as shown in the structure of FIG. 9.

For illustrative purposes, only one structure is shown in FIG. 27, although there may in fact be two of these structures after the detachment step completes. Among other benefits, this may allow for double-side substrate manufacturing, resulting in two times production capability per one-time manufacturing.

After intermediate layers 310 are removed, top layers 312 include specific physical features. The physical features that are characteristic of the removal of intermediate layers 310 are on top surfaces of top layers 312, which are subsequently used to form upper pads 2314 of FIG. 1. For example, the physical features may include, without limitation, rough surfaces, uneven surfaces, concave surfaces, removal marks, etched marks, or laser marks. Among other benefits, the physical features may provide improved adhesion for a material to form directly on a surface with the physical features. As an example, a structure of a material that has been chemically etched may have a rough surface, which has additional surface areas for forming another material thereon, thereby strengthening a bond between the materials. The rough surfaces are neither flat nor smooth. The rough surfaces of a structure have a texture, which is quantified by deviations in the direction of a normal vector of a real surface from its ideal form. The structure includes the rough surfaces if the deviations are greater than a predetermined threshold value of roughness.

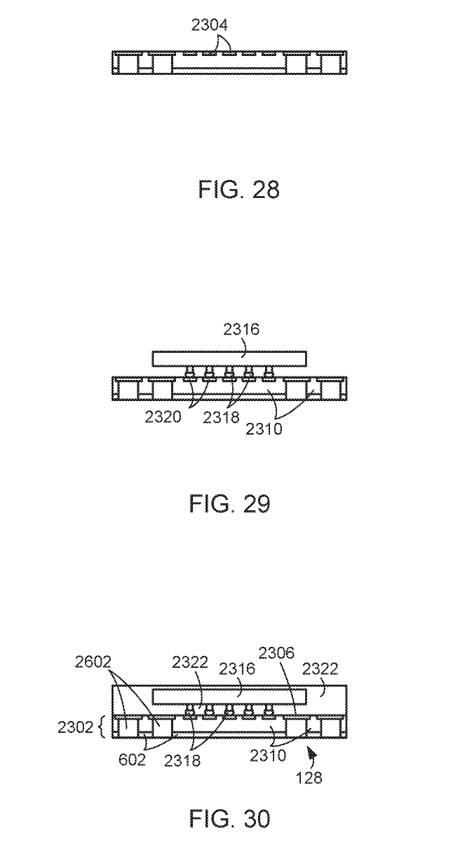

FIG. 28 illustrates removal of top layers 312, in accordance with a third removal step. For example, the third removal step may employ chemical etching or any other chemical and mechanical removal method. Interior pads 2304, system pads 2306, exterior pads 2308, and a top surface of dielectric layer 2310 are exposed after top layers 312 are removed. The third removal step can include etching or any other chemical and mechanical methods.

After top layers 312 are removed, upper pads 2314 include specific physical features. The physical features that are characteristic of the removal of top layers 312 are on sidewalls of upper pads 2314. For example, the physical features may include, without limitation, rough surfaces, uneven surfaces, concave surfaces, removal marks, etched marks, or laser marks. Among other benefits, the physical features may provide improved adhesion for a material to form directly on a surface with the physical features. As an example, a structure of a material that has been chemically etched may have a rough surface, which has additional surface areas for forming another material thereon, thereby strengthening a bond between the materials. The rough surfaces are neither flat nor smooth. The rough surfaces of a structure have a texture, which is quantified by deviations in the direction of a normal vector of a real surface from its ideal form. The structure includes the rough surfaces if the deviations are greater than a predetermined threshold value of roughness.

FIG. 29 illustrates attachment of integrated circuit 2316, in accordance with an attachment step. Integrated circuit 2316 is attached to interior pads 2304 using internal connectors 2318. Integrated circuit 2316 is mounted over dielectric layer 2310. Integrated circuit 116 is directly over interior pads 2304. For example, integrated circuit 2316 may be mounted using a jig, a pick and place equipment, any other assembly device, or any other mounting mechanism.

FIG. 30 illustrates formation of encapsulation 2322, in accordance with a molding step. Encapsulation 2322 is formed over integrated circuit 2316 and support structure 2302. For example, encapsulation 2322 may be formed using a molded underfill (MUF), or any molding material. Encapsulation 2322 is between support structure 2302 and integrated circuit 2316. Encapsulation 2322 is under integrated circuit 2316 and around internal connectors 2318. Encapsulation 2322 is directly on a portion of dielectric layer 2310.

After completion of the molding step, the manufacturing process continues with a second attachment step. In the second attachment step, base conductive layers 602 are removed. Vias 2602 are partially removed to form interior pillars 2338 of FIG. 23 and exterior pillars 2340 of FIG. 23. Dielectric layer 2310 is exposed after base conductive layers 602 are removed. For example, base conductive layers 602 and vias 2602 may be removed by employing chemical etching, or any other chemical and mechanical removal method.

After base conductive layers 602 are removed, dielectric layer 110, interior pillars 2338, and exterior pillars 2340 include specific physical features. The physical features that are characteristic of the removal of base conductive layers 602 are on bottom surfaces of dielectric layer 110, interior pillars 2338, and exterior pillars 2340. For example, the physical features may include, without limitation, rough surfaces, uneven surfaces, concave surfaces, removal marks, etched marks, or laser marks. Among other benefits, the physical features may provide improved adhesion for a material to form directly on a surface with the physical features. As an example, a structure of a material that has been chemically etched may have a rough surface, which has additional surface areas for forming another material thereon, thereby strengthening a bond between the materials. The rough surfaces are neither flat nor smooth. The rough surfaces of a structure have a texture, which is quantified by deviations in the direction of a normal vector of a real surface from its ideal form. The structure includes the rough surfaces if the deviations are greater than a predetermined threshold value of roughness.

The second attachment step attaches external connectors 2324 of FIG. 1. External connectors 2324 are formed below support structure 2302. External connectors 2324 are attached to interior pillars 2338. For example, external connectors 124 may be attached using a solder ball mount (SBM) method or any other mounting method. Also, for example, external connectors 124 may be formed using solder, a metallic material, or a metal alloy.

### 5.0 Support Structure with Pillars on Pads

5.1. Structural Overview

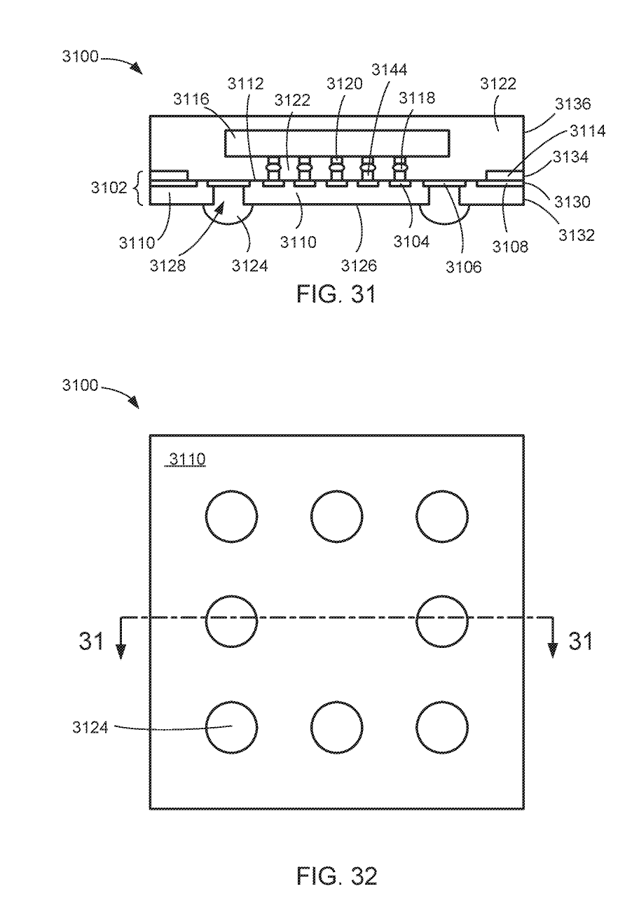

FIG. 31 is a cross-sectional view of an integrated circuit packaging system 3100 in which the techniques described herein may be practiced, according to an embodiment. Integrated circuit packaging system 3100 includes a support structure 3102. Support structure 3102 includes a number of interior pads 3104, system pads 3106, and exterior pads 3108. Interior pads 3104, system pads 3106, and exterior pads 3108 are structures that are used to physically attach or electrically connect to an integrated circuit or an electrical component.

Support structure 3102 includes a dielectric layer 3110, which is an electrical insulator. Dielectric layer 3110 is formed over around interior pads 3104, system pads 3106, and exterior pads 3108. Top surfaces of interior pads 3104, system pads 3106, and exterior pads 3108 are exposed from dielectric layer 3110. Dielectric layer 3110 is directly on sidewalls of interior pads 3104, system pads 3106, and exterior pads 3108. Dielectric layer 3110 is directly on bottom surfaces of interior pads 3104 and exterior pads 3108. Dielectric layer 3110 is partially directly on bottom surfaces of system pads 3106. Top surfaces of dielectric layer 3110, interior pads 3104, system pads 3106, and exterior pads 3108 are coplanar with each other. Interior pads 3104, system pads 3106, and exterior pads 3108 are embedded within a top portion of dielectric layer 3110.

For example, dielectric layer 3110 may be formed using, without limitation, a non-photoimageable dielectric (NPID), an insulation material, a dielectric film, or any other dielectric materials with predetermined physical properties. The predetermined physical properties include, without limitation, a coefficient of thermal expansion (CTE), a glass transition temperature (Tg), and/or a modulus. The predetermined physical properties have been described in details above.

Interior pads 3104, system pads 3106, and exterior pads 3108 are formed at a top side 3112 of dielectric layer 3110 of support structure 3102. A number of interior pads 3104 are formed immediately adjacent each other. A number of interior pads 3104 are formed in a cluster at an interior area of support structure 3102. A number of system pads 3106 are formed around or surrounding interior pads 3104. A number of interior pads 3104 are directly between a system pad 3106 and another system pad 3106. Exterior pads 3108 are formed at an exterior area of support structure 3102. System pads 3106 are directly in between interior pads 3104 and exterior pads 3108.

Support structure 3102 is a single-layer support structure since support structure 3102 includes only one layer, such as dielectric layer 3110. For example, support structure 3102 may also represent, without limitation, a substrate, a carrier, or an ETS. Support structure 3102 includes upper pads 3114 over top side 3112 of dielectric layer 3110. Upper pads 3114 are directly on top side 3112 of dielectric layer 3110 and top sides of exterior pads 3108.

Among other potential benefits, a support structure 3102 having a dielectric layer 3110 enhances adhesion between the dielectric layer 3110 and traces (not shown), interior pads 3104, system pads 3106, and exterior pads 3108, thereby enhancing trace and pad protection. A support structure 3102 having a dielectric layer 3110 may furthermore eliminate delamination of traces and pads in the support structure 3102 by reducing peel strength of the traces and pads. A support structure 3102 having a dielectric layer 3110 that is formed without laser drilling may furthermore enable lower cost substrate.

Integrated circuit packaging system 3100 includes an integrated circuit 3116 and internal connectors 3118. Integrated circuit 3116 is a semiconductor component. For example, integrated circuit 3116 may be, without limitation, an integrated circuit die, a flip-chip, or other suitable semiconductor components.

Integrated circuit 3116 is mounted over support structure 3102. An active side with active circuit of integrated circuit 3116 is facing downwardly towards top side 3112 of dielectric layer 3110. Integrated circuit 3116 includes contacts 3120 that are electrically connected to support pillars 3144. Internal connectors 3118 electrically connect and physically attach contacts 3120 and support pillars 3144. Support pillars 3144 are electrical connectors that are used for mounting and attaching integrated circuit 3116.

Integrated circuit packaging system 3100 includes an encapsulation 3122, which may be, for example, an insulation cover, a package body, or a molded structure of a semiconductor package. Encapsulation 3122 protects, for example, a component and electrical connectors. Encapsulation 3122 covers a top side of support structure 3102, integrated circuit 3116, contacts 3120, and internal connectors 3118. Encapsulation 3122 is formed directly on the top side of support structure 3102, integrated circuit 3116, contacts 3120, internal connectors 3118, interior pads 3104, system pads 3106, and upper pads 3114.

Integrated circuit packaging system 3100 includes external connectors 3124. External connectors 3124 are electrical connectors. For example, external connectors 3124 may interconnect integrated circuit packaging system 3100 and an external system (not shown), such as an electrical device. External connectors 3124 are formed at a bottom side 3126 of support structure 3102. External connectors 3124 are within holes 3128 of dielectric layer 3110. External connectors 3124 are directly on interior sidewalls of dielectric layer 3110 and bottom surfaces of system pads 3106. External connectors 3124 extend below bottom side 3126 of support structure 3102 to provide a spacing above the external system for mounting integrated circuit packaging system 3100 above the external system.

In an embodiment, exterior pad sidewalls 3130 of exterior pads 3108 may be exposed from dielectric layer 3110. Exterior pad sidewalls 3130 may be coplanar with a combination of dielectric sidewalls 3132 of dielectric layer 3110, upper pad sidewalls 3134 of upper pads 3114, and encapsulation sidewalls 3136 of encapsulation 3122. For example, exterior pad sidewalls 3130 may be coplanar with dielectric sidewalls 3132, upper pad sidewalls 3134, and encapsulation sidewalls 3136. Also, for example, exterior pad sidewalls 3130 may be coplanar with dielectric sidewalls 3132 and encapsulation sidewalls 3136.

In an embodiment, upper pad sidewalls 3134 may be exposed from encapsulation 3122. Upper pad sidewalls 3134 may be coplanar with a combination of dielectric sidewalls 3132, exterior pad sidewalls 3130, and encapsulation sidewalls 3136. For example, upper pad sidewalls 3134 may be coplanar with dielectric sidewalls 3132, exterior pad sidewalls 3130, and encapsulation sidewalls 3136. Also, for example, exterior pad sidewalls 3130 may be coplanar with dielectric sidewalls 3132 and encapsulation sidewalls 3136.

For illustrative purposes, exterior pad sidewalls 3130 and upper pad sidewalls 3134 are coplanar with dielectric sidewalls 3132 and encapsulation sidewalls 3136, although it is understood that exterior pad sidewalls 3130 and upper pad sidewalls 3134 may be formed in a different manner. For example, exterior pad sidewalls 3130 and upper pad sidewalls 3134 may be covered by dielectric layer 3110 and encapsulation 3122, respectively.

FIG. 32 is a bottom view of integrated circuit packaging system 3100. Integrated circuit packaging system 3100 includes dielectric layer 3110 around external connectors 3124. For illustrative purposes, only one row of external connectors 3124 are shown on each side of integrated circuit packaging system 3100 with only three external connectors 3124 in each row, although it is understood that integrated circuit packaging system 3100 may include any number of rows of external connectors 3124 on each side of integrated circuit packaging system 3100 and any number of external connectors 3124 per row. Note that the view of FIG. 31 is taken along line 31-31 in FIG. 32.

5.2. Example Manufacturing Processes

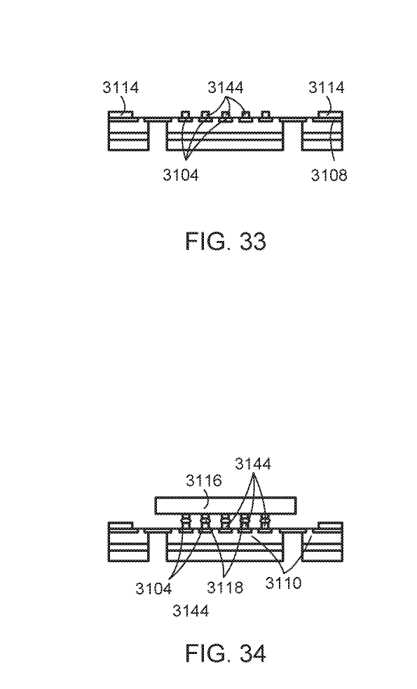

FIG. 33 illustrates the partial removal of top layers 312, in accordance with a third removal step of a process flow for manufacture of a support structure, such as the support structure 3102 of FIG. 31, with pillars on pads. The process flow includes the method steps described above in FIGS. 3-6 and 15-18. Top layers 312 are partially removed to form upper pads 3114 and support pillars 3144. For example, the third removal step may employ chemical etching or any other chemical and mechanical removal method.

After top layers 312 are partially removed, upper pads 3114 and support pillars 3144 include specific physical features. The physical features that are characteristic of the partially removal of top layers 312 are on sidewalls of upper pads 3114 and support pillars 3144. For example, the physical features may include, without limitation, rough surfaces, uneven surfaces, concave surfaces, removal marks, etched marks, or laser marks. Among other benefits, the physical features may provide improved adhesion for a material to form directly on a surface with the physical features. As an example, a structure of a material that has been chemically etched may have a rough surface, which has additional surface areas for forming another material thereon, thereby strengthening a bond between the materials. The rough surfaces are neither flat nor smooth. The rough surfaces of a structure have a texture, which is quantified by deviations in the direction of a normal vector of a real surface from its ideal form. The structure includes the rough surfaces if the deviations are greater than a predetermined threshold value of roughness.

For illustrative purposes, upper pads 3114 are shown to have a width less than a width of exterior pads 3108, although it is understood that upper pads 3114 may be formed in different manners. For example, upper pads 3114 may instead have a width equal to or greater than a width of exterior pads 3108.

For illustrative purposes, support pillars 3144 are shown having a width less than a width of interior pads 3104, although it is understood that support pillars 3144 may be formed in different manners. For example, support pillars 3144 may instead be formed with a width equal to or greater than a width of interior pads 3104.

FIG. 34 illustrates attachment of integrated circuit 1316, in accordance with an attachment step. Integrated circuit 3116 is attached to support pillars 3144 using internal connectors 3118. Integrated circuit 3116 is mounted over dielectric layer 3110. Integrated circuit 3116 is directly over interior pads 3104. For example, integrated circuit 1316 may be mounted using a jig, a pick and place equipment, any other assembly device, or any other mounting mechanism.

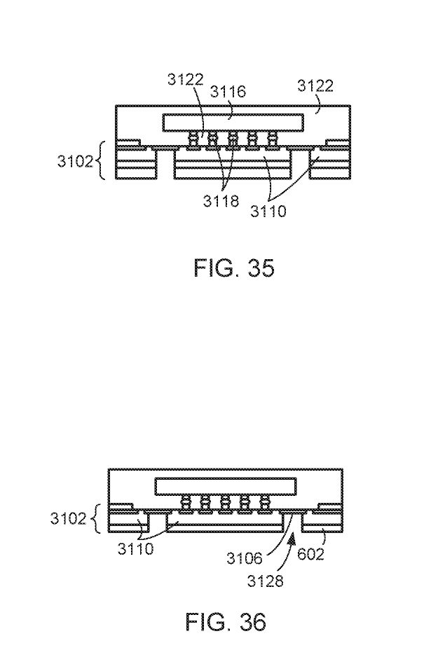

FIG. 35 illustrates formation of encapsulation 3122, in accordance with a molding step. Encapsulation 3122 is formed over integrated circuit 3116 and support structure 3102. For example, encapsulation 3122 may be formed using a molded underfill (MUF), or any molding material. Encapsulation 3122 is under integrated circuit 3116 and around internal connectors 3118. Encapsulation 3122 is directly on a portion of dielectric layer 3110.

FIG. 36 illustrates removal of the detach carrier, in accordance with a fourth removal step. The fourth removal step removes carrier conductive layers 1502 of FIG. 15. Base conductive layers 602 are exposed after carrier conductive layers 1502 are removed. For example, carrier conductive layers 1502 may be removed by employing chemical etching, or any other chemical and mechanical removal method.

After completion of the fourth removal step, the manufacturing process continues with a second attachment step. In the second attachment step, base conductive layers 602 are removed. Dielectric layer 3110 is exposed after base conductive layers 602 are removed. For example, base conductive layers 602 may be removed by employing chemical etching, or any other chemical and mechanical removal method.

After base conductive layers 602 are removed, dielectric layer 3110 include specific physical features. The physical features that are characteristic of the removal of base conductive layers 602 are on a bottom surface of dielectric layer 3110. For example, the physical features may include, without limitation, rough surfaces, uneven surfaces, concave surfaces, removal marks, etched marks, or laser marks. Among other benefits, the physical features may provide improved adhesion for a material to form directly on a surface with the physical features. As an example, a structure of a material that has been chemically etched may have a rough surface, which has additional surface areas for forming another material thereon, thereby strengthening a bond between the materials. The rough surfaces are neither flat nor smooth. The rough surfaces of a structure have a texture, which is quantified by deviations in the direction of a normal vector of a real surface from its ideal form. The structure includes the rough surfaces if the deviations are greater than a predetermined threshold value of roughness.

The second attachment step attaches external connectors 3124 of FIG. 1. External connectors 3124 are attached to or directly on system pads 3106. External connectors 3124 are within holes 3128. For example, external connectors 3124 may be attached using a solder ball mount (SBM) method or any other mounting method. Also, for example, external connectors 3124 may be formed using solder, a metallic material, or a metal alloy.

### 6.0. Example Manufacturing Process Flow

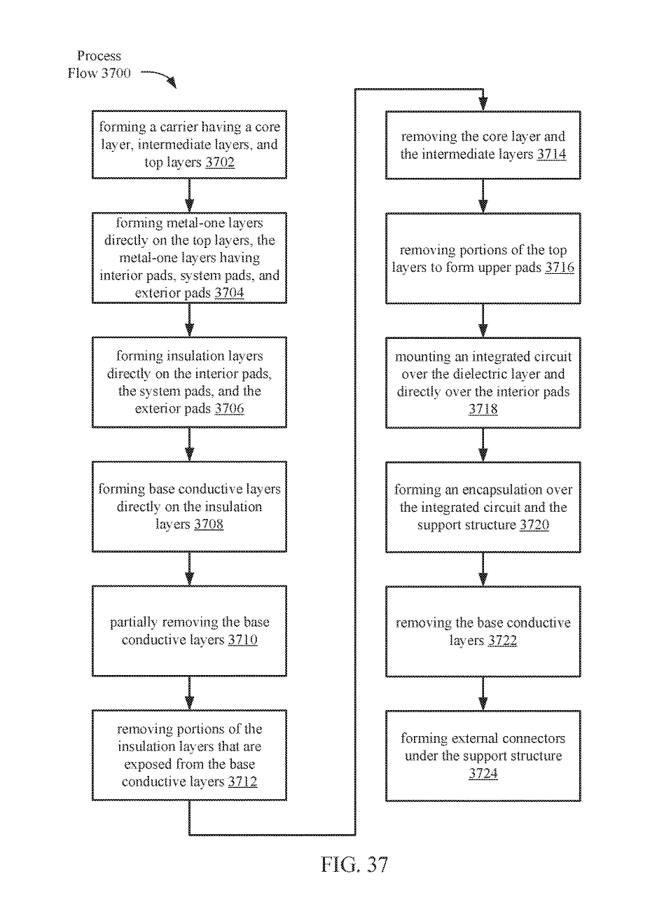

FIG. 37 illustrates an example process flow 3700, in accordance with one or more embodiments. Flow 3700 may be implemented, for example, to form an integrated circuit packaging system such as system 100. FIG. 37 illustrates only one possible flow for practicing the described techniques. Other embodiments may include fewer, additional, or different elements, in varying arrangements. Moreover, it will be recognized that the sequence of blocks is for convenience in explaining the process flow only, as the blocks themselves may be performed in various orders and/or concurrently.

In block 3702, a carrier, such as carrier 302, is formed. The carrier includes a core layer, intermediate layers, and top layers. The intermediate layers are directly on the core layer. The top layers are directly on the intermediate layers. The intermediate layers and the top layers are formed on both bottom and top sides of the carrier.

In block 3704, metal-one layers, such as M1 layers 402, are formed directly on the top layers. The metal-one layers are patterned to form interior pads, system pads, and exterior pads, such as interior pads 104, system pads 106, and exterior pads 108, respectively, of a support substrate, such as support substrate 102. The metal-one layers are patterned to form traces that directly and electrically connect a combination of the interior pads, the system pads, the exterior pads.

In block 3706, insulation layers, such as insulation layers 502, are formed directly on the interior pads, the system pads, the exterior pads, and the traces. The insulation layers include predetermined physical properties, such as some or all of those described above for insulation layers 502. For example, the insulation layers may include a CTE having an approximate range from 0 ppm to 30 ppm. Also, for example, the insulation layers may include a Tg having an approximate range from 200° C. to 350° C. Further, for example, the insulation layers may include a modulus having an approximate range from 5 Gpa to 30 Gpa.

For example, the insulation layers may include, without limitation, a non-photoimageable dielectric (NPID), an insulation material, a dielectric film, and/or any other dielectric materials. Also, for example, the insulation layers may be formed with a dielectric material that is different from other dielectric materials including, without limitation, a PrePreg (PPG) material, a copper clad laminate (CCL), or a solder resist (SR). As another example, in an embodiment, the insulation layers do not include glass that is included in CCL.

In block 3708, base conductive layers, such as base conductive layers 602, are formed directly on the insulation layers.

In block 3710, the base conductive layers are partially removed. Portions of the insulation layers are exposed after the base conductive layers are partially removed.

In block 3712, the portions of the insulation layers that are exposed from the base conductive layers are removed. Holes, such as holes 128, are formed through the insulation layers after the portions of the insulation layers are removed. The holes expose the system pads. One of the insulation layers having the holes is a dielectric layer of the support substrate.

In an embodiment, the dielectric layer is formed with the traces with fine line and space dimensions. For example, the traces may have a line or wire width of less than 20 um. Also, for example, the traces may have a line space of less than 20 um between the traces that are immediately adjacent each other.

In block 3714, portions of the carrier are removed. The portions of the carrier that are removed include the core layer and the intermediate layers, leaving the top layers for subsequent processing.

In block 3716, portions of the top layers are removed to form upper pads, such as upper pads 114, of the support structure.

In block 3718, an integrated circuit, such as integrated circuit 116, is mounted over the dielectric layer and directly over the interior pads. The integrated circuit is attached to the interior pads using internal connectors, such as internal connectors 118.

In block 3720, an encapsulation, such as encapsulation 122, is formed over the integrated circuit and the support structure. The encapsulation is under the integrated circuit, around the internal connectors, and directly on a portion of the dielectric layer.

In block 3722, the base conductive layers are removed. The dielectric layer is exposed after the base conductive layers are removed.

In block 3724, external connectors, such as external connectors 124, are formed under the support structure. The external connectors are attached to or directly on the system pads. The external connectors are formed within the holes of the dielectric layer.

### 7.0. Example Embodiments

Examples of some embodiments are represented, without limitation, in the following clauses:

According to an embodiment, a system comprises: a support structure having an interior pad, a system pad, and a dielectric layer, the system pad adjacent to the interior pad, and the dielectric layer having a bottom surface with a rough texture; an integrated circuit over the dielectric layer; and an encapsulation over the integrated circuit and the support structure.

In an embodiment, the dielectric layer is a non-photoimageable dielectric (NPID) material.

In an embodiment, the dielectric layer includes an interior sidewall with a rough texture.

In an embodiment, the support structure includes an exterior pad, and the system pad is directly in between the interior pad and the exterior pad.

In an embodiment, the system further comprises an external connector within a hole of the dielectric layer.

In an embodiment, the support structure includes a hole and an interior pillar, the hole is directly below the system pad, and the interior pillar is within the hole and directly on the system pad.

In an embodiment, the dielectric layer includes a sidewall coplanar with a sidewall of the encapsulation.

In an embodiment, the interior pad and the system pad are at a top side of the support structure.

In an embodiment, the interior pad is directly under the integrated circuit.

In an embodiment, the system pad includes a bottom surface with a rough texture.

In an embodiment, the interior pad, the system pad, and the dielectric layer include top surfaces, and the top surfaces are coplanar with each other.

According to an embodiment, a system comprises: a support structure having an interior pad, a system pad, and a dielectric layer, the system pad adjacent to the interior pad, the dielectric layer having a bottom surface with a rough texture; an integrated circuit over the dielectric layer; an internal connector connected to the integrated circuit and the support structure; and an external connector attached to the support structure.

In an embodiment, the support structure includes an interior pillar directly on the interior pad, and the internal connector is attached to the interior pillar and the integrated circuit.

In an embodiment, the dielectric layer is a non-photoimageable dielectric (NPID) material.

In an embodiment, the dielectric layer includes an interior sidewall with a rough texture.

In an embodiment, the support structure includes an exterior pad, and the system pad is directly in between the interior pad and the exterior pad.

In an embodiment, the system further comprises an external connector within a hole of the dielectric layer.

In an embodiment, the dielectric layer includes a sidewall coplanar with a sidewall of the encapsulation.

In an embodiment, the interior pad and the system pad are at a top side of the support structure.

According to an embodiment, a method comprises: forming a support structure having an interior pad, a system pad, and a dielectric layer, the system pad adjacent to the interior pad, the dielectric layer having a bottom surface with a rough texture; mounting an integrated circuit over the dielectric layer; and forming an encapsulation over the integrated circuit and the support structure.

In an embodiment, the method includes forming the dielectric layer with a non-photoimageable dielectric (NPID) material.

In an embodiment, the method includes forming the dielectric layer having an interior sidewall with a rough texture.

In an embodiment, the method includes forming an exterior pad, the system pad directly in between the interior pad and the exterior pad.

Other examples of these and other embodiments are found throughout this disclosure.

### 8.0. Extensions and Alternatives

As used herein, the terms “first,” “second,” “certain,” and “particular” are used as naming conventions to distinguish queries, plans, representations, steps, objects, devices, or other items from each other, so that these items may be referenced after they have been introduced. Unless otherwise specified herein, the use of these terms does not imply an ordering, timing, or any other characteristic of the referenced items.

In the drawings, the various components are depicted as being communicatively coupled to various other components by arrows. These arrows illustrate only certain examples of information flows between the components. Neither the direction of the arrows nor the lack of arrow lines between certain components should be interpreted as indicating the existence or absence of communication between the certain components themselves. Indeed, each component may feature a suitable communication interface by which the component may become communicatively coupled to other components as needed to accomplish any of the functions described herein.

In the foregoing specification, embodiments of the invention have been described with reference to numerous specific details that may vary from implementation to implementation. Thus, the sole and exclusive indicator of what is the invention, and is intended by the applicants to be the invention, is the set of claims that issue from this application, in the specific form in which such claims issue, including any subsequent correction. In this regard, although specific claim dependencies are set out in the claims of this application, it is to be noted that the features of the dependent claims of this application may be combined as appropriate with the features of other dependent claims and with the features of the independent claims of this application, and not merely according to the specific dependencies recited in the set of claims. Moreover, although separate embodiments are discussed herein, any combination of embodiments and/or partial embodiments discussed herein may be combined to form further embodiments.

Any definitions expressly set forth herein for terms contained in such claims shall govern the meaning of such terms as used in the claims. Hence, no limitation, element, property, feature, advantage or attribute that is not expressly recited in a claim should limit the scope of such claim in any way. The specification and drawings are, accordingly, to be regarded in an illustrative rather than a restrictive sense.

What is claimed is:

1. A system comprising:
a support structure having an interior pad, a system pad, and a dielectric layer, the system pad adjacent to the interior pad, the dielectric layer having a bottom surface with a rough texture;
an integrated circuit over the dielectric layer; and
an encapsulation over the integrated circuit and the support structure.

2. The system as recited in claim 1, wherein the dielectric layer is a non-photoimageable dielectric (NPID) material.

3. The system as recited in claim 1, wherein the dielectric layer includes an interior sidewall with a rough texture.

4. The system as recited in claim 1, wherein the support structure includes an exterior pad, the system pad directly in between the interior pad and the exterior pad.

5. The system as recited in claim 1, further comprising an external connector within a hole of the dielectric layer.

6. The system as recited in claim 1, wherein the support structure includes a hole and an interior pillar, the hole directly below the system pad, the interior pillar within the hole and directly on the system pad.

7. The system as recited in claim 1, wherein the dielectric layer includes a sidewall coplanar with a sidewall of the encapsulation.

8. The system as recited in claim 1, wherein the interior pad and the system pad are at a top side of the support structure.

9. A system comprising:
a support structure having an interior pad, a system pad, and a dielectric layer, the system pad adjacent to the interior pad, the dielectric layer having a bottom surface with a rough texture;
an integrated circuit over the dielectric layer;
an internal connector connected to the integrated circuit and the support structure; and
an external connector attached to the support structure.

10. The system as recited in claim 9, wherein the support structure includes an interior pillar directly on the interior pad, and the internal connector is attached to the interior pillar and the integrated circuit.

11. The system as recited in claim 9, wherein the dielectric layer is a non-photoimageable dielectric (NPID) material.

12. The system as recited in claim 9, wherein the dielectric layer includes an interior sidewall with a rough texture.

13. The system as recited in claim 9, wherein the support structure includes an exterior pad, the system pad directly in between the interior pad and the exterior pad.

14. The system as recited in claim 9, further comprising an external connector within a hole of the dielectric layer.

15. The system as recited in claim 9, wherein the dielectric layer includes a sidewall coplanar with a sidewall of the encapsulation.

16. The system as recited in claim 9, wherein the interior pad and the system pad are at a top side of the support structure.

17. A method comprising:
forming a support structure having an interior pad, a system pad, and a dielectric layer, the system pad adjacent to the interior pad, the dielectric layer having a bottom surface with a rough texture;
mounting an integrated circuit over the dielectric layer; and
forming an encapsulation over the integrated circuit and the support structure.

18. The method as recited in claim 17, wherein forming the support structure includes forming the dielectric layer with a non-photoimageable dielectric (NPID) material.

19. The method as recited in claim 17, wherein forming the support structure includes forming the dielectric layer having an interior sidewall with a rough texture.

20. The method as recited in claim 17, wherein forming the support structure includes forming an exterior pad, the system pad directly in between the interior pad and the exterior pad.
